(19) United States
(12) Patent Application Publication
(10) Pub. No.: US 2026/0303112 A1
(43) Pub. Date: Oct. 1, 2026

(54) BALANCED MONOTONIC SUCCESSIVE APPROXIMATION ADC

(71) Applicant: SEMICONDUCTOR COMPONENTS INDUSTRIES, LLC, Scottsdale, AZ (US)

(72) Inventor: Xintian SHI, Hauterive (CH)

(73) Assignee: SEMICONDUCTOR COMPONENTS INDUSTRIES, LLC, Scottsdale, AZ (US)

(21) Appl. No.: 19/311,895

(22) Filed: Aug. 27, 2025

Related U.S. Application Data
(60) Provisional application No. 63/777,957, filed on Mar. 26, 2025.

(51) Int. Cl. H03M 1/38

(52) U.S. Cl. CPC H03M 1/38

(57) ABSTRACT

One illustrative n-bit balanced monotonic SAR ADC includes: a sample and hold element, a first bank of capacitances, a comparator, and control logic. The sample and hold element is coupled to a first sensing node to provide an input voltage. The first bank of capacitances includes: n−1 upper capacitances each having a switchable input node that is initially coupled to an upper reference voltage and is switchable to a lower reference voltage; and n−1 lower capacitances each having a switchable input node that is initially coupled to the lower reference voltage and is switchable to the upper reference voltage. The comparator provides a bit decision signal based on a voltage of a first sensing node. The logic controls switches for the first bank of capacitances based on the bit decision signal, thereby causing the bit decision signal to provide a sequential binary representation of the input voltage.

### CROSS REFERENCE TO RELATED APPLICATIONS

The present application claims benefit of provisional U.S. application 63/777,7957, filed 2025 Mar. 26 and titled “A novel monotonic capacitive DAC switching method for SAR ADCs” by inventor X. Shi. The foregoing application is hereby incorporated herein by reference.

### TECHNICAL FIELD

The present application relates to circuits and methods for analog-to-digital (A/D) conversion, and more particularly, to A/D conversion circuits and methods implementing a successive approximation register (SAR) approach with charge redistribution.

### BACKGROUND

Of the various existing A/D converter (ADC) designs, those using the successive approximation register (SAR) approach with charge redistribution among a bank of capacitors may be particularly suited to low power applications. Their main limitation is the sequential conversion process requiring multiple steps to complete digitization of each sample. This limitation may be somewhat offset by features such as energy efficiency in that SAR-ADC designs using capacitive arrays for charge redistribution routinely demonstrate the minimum power dissipation among comparable ADC designs. Moreover, many of these designs demonstrate high linearity, providing accurate operation across the maximal dynamic range, which extends rail-to-rail making the design suitable for use in low voltage implementations.

There is nevertheless room for improvement in these ADC designs. Recent efforts include reducing total capacitance of the capacitor bank by splitting it into segments coupled by series capacitors as seen in, e.g., Savitha and Reddy, “A 14-bit Dual-Split Capacitor Array DAC Design Based Successive Approximation ADC”, International Journal of Recent Technology and Engineering, v8:1, May 2019. Another approach to reducing total capacitance is a monotonic switching process such as that taught by Chun-Cheng Liu et al., “A 10-bit 50 MS/s SAR ADS with a Monotonic Capacitor Switching Procedure”, IEEE J. of Solid-State Circuits, v45:4, April 2010. While the latter approach may offer a halving of required capacitance and an 81% reduction in power consumption, it unfortunately demonstrates reduced precision due to parasitic capacitance effects and reduced accuracy due to offset variation. Better solutions are sought.

### SUMMARY

The foregoing issues are at least in part addressed by a balanced monotonic successive approximation ADCs and methods that may be particularly suitable for use in low power sensors. One illustrative n-bit balanced monotonic SAR ADC includes: a sample and hold element, a first bank of capacitances, a comparator, and control logic. The sample and hold element is coupled to a first sensing node to provide an input voltage. The first bank of capacitances includes: n−1 upper capacitances each having a switchable input node that is initially coupled to an upper reference voltage and is switchable to a lower reference voltage; and n−1 lower capacitances each having a switchable input node that is initially coupled to the lower reference voltage and is switchable to the upper reference voltage. The comparator is configured to provide a bit decision signal based at least in part on a voltage of a first sensing node. The logic is configured to control switches for the first bank of capacitances based on the bit decision signal, thereby causing the bit decision signal to provide a sequential binary representation of the input voltage.

An illustrative digitization method includes: coupling an input voltage to a first sensing node; using a comparator to produce a bit decision signal based at least in part on a voltage of the first sensing node; and altering the voltage of the first sensing node in binary-weighted steps by controlling switches for a first bank of capacitances based on the bit decision signal, thereby causing the bit decision signal to provide a sequential n-bit binary representation of the input voltage. The first bank of capacitances includes: n−1 upper capacitances each having a switchable input node that is initially coupled to an upper reference voltage and is switchable to a lower reference voltage; and n−1 lower capacitances each having a switchable input node that is initially coupled to the lower reference voltage and is switchable to the upper reference voltage.

An illustrative sensor controller includes: one or more input pins configured to accept an analog signal from a transducer; and a balanced monotonic successive approximation analog to digital converter configured to produce a digital signal representation of the analog signal.

Each of the foregoing examples can be employed individually or in conjunction and may include one or more of the following optional features in any suitable combination: 1. the sample and hold element provides the input voltage as a differential voltage between the first sensing node and a second sensing node. 2. the comparator provides the bit decision signal based on a voltage between the first sensing node and the second sensing node. 3. the ADC includes a second bank of capacitances configured to alter the voltage of the second sensing node in binary-weighted steps. 4. the second bank includes: n−1 upper capacitances each having a switchable input node that is initially coupled to an upper reference voltage and is switchable to a lower reference voltage; and n−1 lower capacitances each having a switchable input node that is initially coupled to the lower reference voltage and is switchable to the upper reference voltage. 5. the logic operates in a sequence of phases including a sampling phase followed by n phases representable by an index i taking values from n−1 to 0. 6. when the bit decision signal for phase i is zero, with i>0, the logic is configured to switch a corresponding lower capacitance in the first bank from the lower reference voltage to the upper reference voltage and a corresponding upper capacitance in the second bank from the upper reference voltage to the lower reference voltage. 7. when the bit decision signal for phase i is one, with i>0, the logic is configured to switch a corresponding upper capacitance in the first bank from the upper reference voltage to the lower reference voltage and a corresponding lower capacitance in the second bank from the lower reference voltage to the upper reference voltage. 8. the sample and hold element includes: a shorting switch configured to open or close a connection between a first sample node and a second sample node; a first sample capacitance coupled between the first sample node and the first sensing node; a second sample capacitance coupled between the second sample node and the second sensing node; a first sample switch configured to couple the first sample node to a first voltage input while the shorting switch is open; and a second sample switch configured to couple the second sample node to a second voltage input while the shorting switch is open. 9. the sample and hold element includes: a first reset switch that couples the first sensing node to a mean voltage between the upper reference voltage and the lower reference voltage while the shorting switch is open; and a second reset switch that couples the second sensing node to the mean voltage while the shorting switch is open. 10. the first bank of capacitances includes a C₀ capacitance coupled between the lower reference voltage and the first sensing node. 11. the n−1 upper capacitances are given by Cᵢ=2ⁱ(C₀/2), i=0 to n−2, and wherein the n−1 lower capacitances are given by Cᵢ=2ⁱ(C₀/2), i=0 to n−2. 12. the n-bit analog to digital converter of claim 1, wherein the lower reference voltage is ground voltage. 13. the analog signal is a single-ended signal, and the sensor controller includes an operational amplifier that amplifies the analog signal to produce a differential analog signal for the balanced monotonic successive approximation analog to digital converter.

### BRIEF DESCRIPTION OF THE DRAWINGS

FIG. 1 shows an illustrative non-monotonic successive approximation ADC.

FIG. 2 shows a digitization method implemented by the ADC of FIG. 1.

FIG. 3 is a graph of illustrative sensing node voltages in the ADC of FIG. 1.

FIG. 4 is a schematic of an illustrative unbalanced successive approximation ADC.

FIG. 5 shows a digitization method implemented by the ADC of FIG. 4.

FIG. 6 is a graph of illustrative sensing node voltages in the ADC of FIG. 4.

FIG. 7 shows an illustrative balanced, monotonic successive approximation ADC.

FIG. 8 shows a digitization method implemented by the ADC of FIG. 7.

FIG. 9 is a graph of illustrative sensing node voltages in the ADC of FIG. 7.

FIG. 10 is a schematic of an illustrative low power sensor.

### DETAILED DESCRIPTION

The drawings and following description do not limit the disclosure, but on the contrary, they provide the foundation for one of ordinary skill in the art to understand all modifications, equivalents, and alternatives falling within the scope of the claim language.

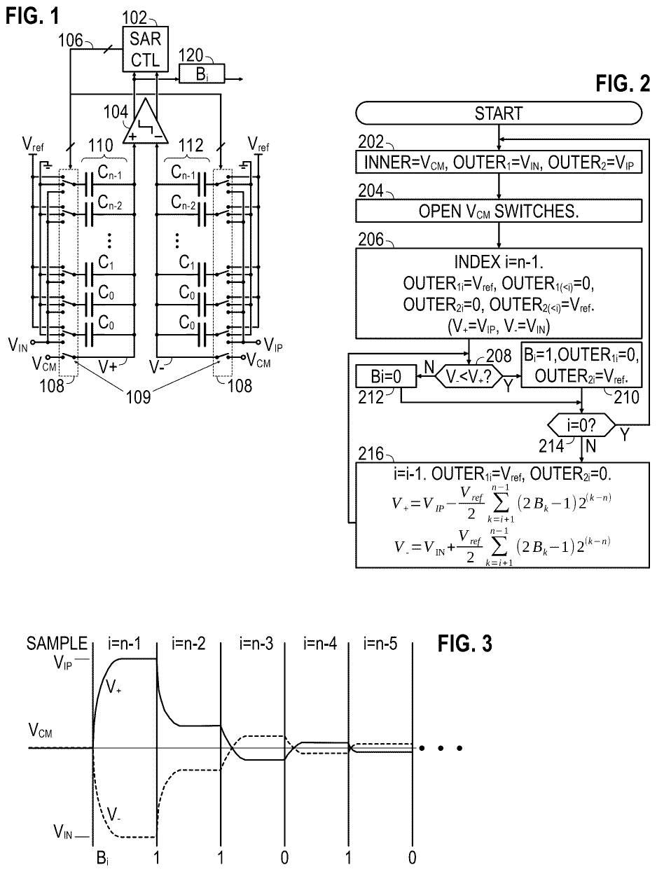

As a first baseline for comparison, FIG. 1 shows an illustrative non-monotonic successive approximation ADC. Control logic 102 operates on a bit decision signal from a comparator 104 to produce switch control signals 106 for a switch arrangement 108. A first bank of capacitances 110 has a set of capacitances each coupled between a first sensing node V+ and a switchable input node controlled via the switch arrangement 108. Similarly, a second bank of capacitances 112 has a set of capacitances each coupled between a second sensing node V− and a switchable input node controlled via the switch arrangement 108. Each of the switchable input nodes in the first bank can be coupled to an upper reference voltage V_{ref}, a lower reference voltage (shown here as a ground connection), and negative input voltage V_{IN}. Each of the switchable input nodes in the second bank can be coupled to the upper reference voltage V_{ref}, the lower reference voltage (ground), and a positive input voltage V_{IP}.

The switch arrangement further includes reset switches 109 that couple the sensing nodes V+, V− to a common mode voltage V_{CM} while the switchable input nodes of the first bank are coupled to the negative input voltage V_{IN} and the switchable input nodes of the second bank are coupled to the positive input voltage V_{IP}. The common mode voltage may be the mean voltage between the first and second reference voltages. This reset may be performed to sample the differential input voltage before each digitization cycle.

In this example, the capacitances in each bank are provided with a binary weighting, with capacitance Cᵢ=2ⁱCᵤ, i=0 to n−1. (Each bank includes an extra C₀ capacitance for completing the final charge redistribution.) Cᵤ is a unit capacitance selected to provide the desired tradeoff between signal to noise ratio and settling time. Alternative split-bank configurations are possible and may desirably provide a reduction in total capacitance at the expense of an increase in complexity of implementation (and explanation). See, e.g., Savitha and Reddy, “A 14-bit Dual-Split Capacitor Array DAC Design Based Successive Approximation ADC”, International Journal of Recent Technology and Engineering, v8:1, May 2019. Such alternative configurations are compatible with, and contemplated for, each of the examples provided herein, but do not aid in the explanation of the relevant principles disclosed herein.

As the control logic 102 iterates through the various phases of the digitization cycle, the comparator 104 produces a bit decision signal indicating whether the first sensing node V+ has a higher voltage than the second sensing node V−. If the phases are associated with an index i that progresses from n−1 to 0 (n being the number of bits desired in the digital representation of the input voltage) the bit decision signal Bᵢ takes on the value of the ith bit in the digital representation in the ith phase of the digitization cycle. A register 120 may capture these bit values to export the digital representation in a parallel or serial fashion. In at least some contemplated implementations, register 120 is a shift register.

The operation of the ADC is now described in connection with the flow diagram of FIG. 2. The digitization cycle begins in block 202 with an initial sampling phase, during which the control logic connects sensing nodes V+, V−, and hence the inner nodes of the capacitances in the first and second banks 110, 112, to the common mode voltage V_{CM} via reset switches 109. The control logic connects the outer nodes (previously referenced as the switchable input nodes) of the first bank 110 to the negative input voltage V_{IN} and the outer nodes of the second bank 112 to the positive input voltage V_{IP}. The sampling phase concludes in block 204 with the control logic opening the reset switches 109.

After the sampling phase, the control logic sets the index i equal to n−1 in block 206. In the first bank, the control logic connects the switchable node of capacitance Cᵢ to the upper reference voltage V_{ref} and the switchable nodes of the remaining capacitances C_{k<i} to the lower reference voltage 0. In the second bank, the control logic connects the switchable node of capacitance Cᵢ to the lower reference voltage 0 and the switchable nodes of the remaining capacitances C_{k<i} to the upper reference voltage V_{ref}. These connections cause the first sensing node V+ to equal the positive input voltage V_{IP} and the second sensing node V− to equal the negative input voltage V_{IN}.

In block 208, the comparator evaluates whether the first sensing node has a higher voltage than the second sensing node, and if so, asserts the bit decision signal Bᵢ in block 210. The control logic responsively reconnects the switchable node of capacitance Cᵢ in the first bank to the lower reference voltage and the switchable node of Cᵢ in the second bank to the upper reference voltage. Otherwise, in block 212 the comparator de-asserts the bit decision signal Bᵢ.

In block 214, the control logic determines whether the final phase (in which i=0) has been reached. If so, the logic returns to block 202 to commence digitization of a new sample. Otherwise, the control logic decrements the phase index i in block 216 and connects the switchable node of capacitance Cᵢ in the first bank to the upper reference voltage and switchable node of capacitance Cᵢ in the second bank to the lower reference voltage. This connection applies a binary-weighted step to the voltages of the first and second sensing nodes, yielding the voltages given by the equations in FIG. 2. Blocks 208-216 are repeated until index i reaches zero.

FIG. 3 shows the voltages of sensing nodes V+, V− for the sampling phase and first five digitization phases of an illustrative input voltage. During the sampling phase, the sensing nodes are connected to the common mode voltage V_{CM}. The switching array configuration created in block 206 causes the first sensing node to converge to the positive input voltage V_{IP} and the second sensing node to converge to the negative input voltage V_{IN}. When the phase index i=n−2, sensing node voltages are each shifted by V_{ref}/4. When the phase index i=n−3, the sensing node voltages are each shifted by V_{ref}/8. The direction of these shifts is determined by the bit decision signal Bᵢ. Each comparison by the comparator has the sensing node voltages spaced symmetrically about the common mode voltage, thereby maximizing accuracy.

It is noted here that blocks 206 and 216 represent a redistribution of charge among the capacitances in each bank. It is further noted that block 210 represents a reversal of the immediately preceding redistribution, increasing power consumption. This extra power consumption can be avoided using a monotonic design that avoids reversing previous redistributions.

It is further noted that each capacitance bank in FIG. 1 has a total capacitance of 2ⁿCᵤ. As previously mentioned, certain reductions can be achieved by splitting the capacitance bank into segments separated by series capacitances. In both cases, monotonic designs may offer an additional benefit of halving the total capacitance.

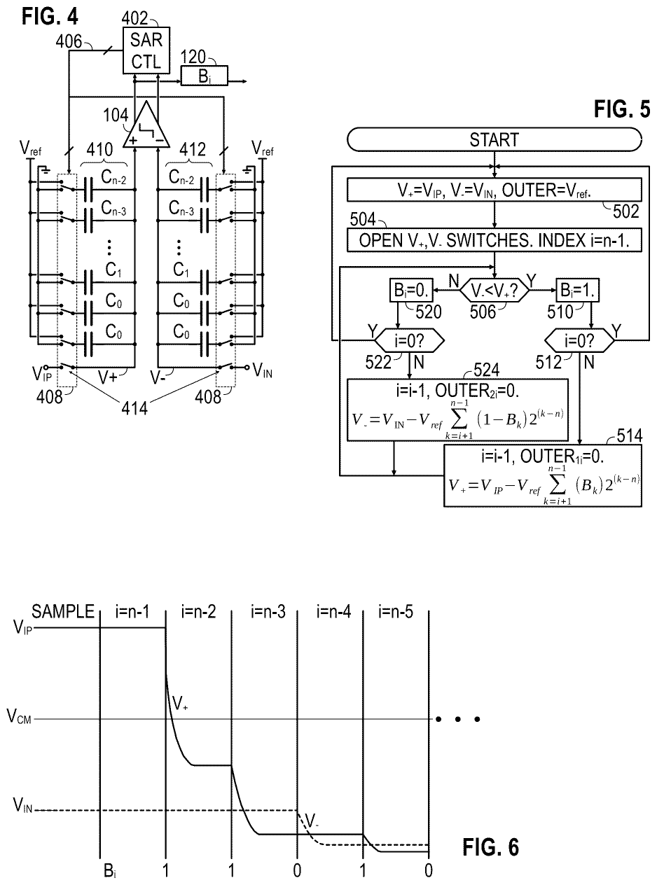

FIG. 4 shows a monotonic design that may reduce power consumption and total capacitance of each bank. Control logic 402 operates on the bit decision signal from a comparator 104 to produce switch control signals 406 for a switch arrangement 408. A first bank of capacitances 410 has a set of capacitances each coupled between a first sensing node V+ and a switchable input node controlled via the switch arrangement 408. Similarly, a second bank of capacitances 412 has a set of capacitances each coupled between a second sensing node V− and a switchable input node controlled via the switch arrangement 408. Each of the switchable input nodes in the first and second banks can be coupled to an upper reference voltage V_{ref} or a lower reference voltage (shown here as a ground connection).

The switch arrangement further includes sampling switches 414 that connect the sensing nodes V+, V− to the positive and negative input voltages, respectively, while the switchable nodes of the first and second banks are connected to the upper reference voltage V_{ref}. Once the bank capacitances have been charged, the sampling switches 414 are opened before the digitization cycle begins.

The capacitances in each bank are similar to the banks of FIG. 1 with the largest capacitance Cₙ₋₁ omitted. As the control logic 402 iterates through the various phases of the digitization cycle, the comparator 104 produces a bit decision signal indicating whether the first sensing node V+ has a higher voltage than the second sensing node V−. If the phases are associated with an index i that progresses from n−1 to 0 (n being the number of bits desired in the digital representation of the input voltage) the bit decision signal Bᵢ takes on the value of the ith bit in the digital representation in the ith phase of the digitization cycle. A register 120 may capture these bit values to export the digital representation in a parallel or serial fashion. In at least some contemplated implementations, register 120 is a shift register.

The operation of the ADC is now described in connection with the flow diagram of FIG. 5. The digitization cycle begins in block 502 with an initial sampling phase, during which the control logic connects the first sensing node V+ to the positive input voltage V_{IP} and the second sensing node V− while connecting the switchable nodes of the capacitances in both banks to the upper reference voltage V_{ref}. The sampling phase concludes in block 504 with the control logic opening the sampling switches 414 and setting the phase index i to n−1.

In block 506, the comparator evaluates whether the first sensing node has a higher voltage than the second sensing node, and if so, asserts the bit decision signal Bᵢ in block 510. In block 512, the control logic determines whether the final phase (in which index i=0) has been reached. If so, the logic returns to block 502 to commence digitization of a new sample. If the final phase has not been reached, the control logic decrements the index i and connects the switchable node of capacitance Cᵢ in the first bank to the lower reference voltage, thereby altering the voltage of the first sensing node as provided by the equation in block 514.

Otherwise, if the first sensing node has a lower voltage than the second sensing node, the comparator de-asserts the bit decision signal Bᵢ in block 520. In block 522, the control logic determines whether the final phase (in which index i=0) has been reached. If so, the logic returns to block 502 to commence digitization of a new sample. If the final phase has not been reached, the control logic decrements the index i in block 524 and connects the switchable node of the capacitance Cᵢ in the second bank to the lower reference voltage, thereby altering the voltage of the second sensing node as provided by the equation in block 524. Blocks 506-524 are repeated until index i reaches zero.

FIG. 6 shows the voltages of sensing nodes V+, V− for the sampling phase and first five digitization phases of an illustrative input voltage. During the sampling phase, the first and second sensing nodes are respectively connected to the positive and negative input voltages V_{IP}, V_{IN}. These voltages are retained during the initial digitization phase when i=n−1. When the phase index i=n−2, one of the sensing node voltages is shifted by V_{ref}/2. When the phase index i=n−3, one of sensing node voltages is shifted by V_{ref}/4. The control logic determines which of the sensing node voltages is shifted based on the bit decision signal Bᵢ.

While this approach avoids reversing any preceding charge redistributions, it is noted here that only the phase with index i=n−1 has the sensing node voltages spaced symmetrically about the common mode voltage. Thereafter, the symmetry is lost, and the comparator operation becomes sensitive to offset voltages and associated nonlinearities. Accuracy is consequently reduced for this design.

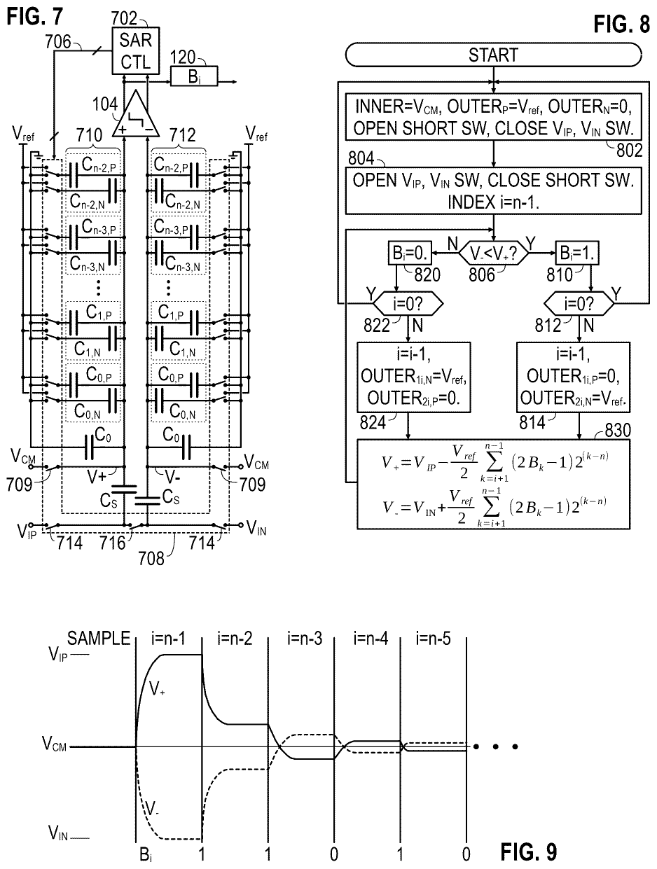

Accordingly, the balanced monotonic SAR ADC design of FIG. 7 has been developed to regain the accuracy of balanced sensing node voltages while retaining the advantages of monotonic operation. By comparison with FIG. 4, it can be observed that with the exception of the extra C₀ capacitance, each of the Cᵢ capacitances in each bank have been divided into an upper capacitance C_{i, P} and a lower capacitance C_{i,N}. The upper and lower capacitances are half of the size of the corresponding Cᵢ capacitance, i.e.,
C_{i,P}=C_{i,N}=Cᵢ/2=2ⁱ⁻¹Cᵤ, i=0 to n−2.

As will be seen below, the outer nodes of the upper capacitances are initially connected to the upper reference voltage V_{ref}, while the outer nodes of the lower capacitances are initially connected to the lower reference voltage 0.

Control logic 702 operates on the bit decision signal from the comparator 104 to produce switch control signals 706 for the switch arrangement 708. A first bank of capacitances 710 has a set of capacitances each coupled between a first sensing node V+ and a switchable input node controlled via the switch arrangement 708. Similarly, a second bank of capacitances 712 has a set of capacitances each coupled between a second sensing node V− and a switchable input node controlled via the switch arrangement 708. Each of the switchable input nodes in the first and second banks can be coupled to an upper reference voltage V_{ref} or a lower reference voltage (shown here as a ground connection).

In addition to the first and second banks, 710, 712, the design of FIG. 7 provides a first sampling capacitance C_{S} that couples a switchable input node to the first sensing node V+ and a switchable input node, and a second sampling capacitance C_{S} that couples a switchable input node to the second sensing node V−. The switch arrangement further includes reset switches 709 that connect the sensing nodes V+, V− to the common mode voltage V_{CM} during a sampling phase in which sampling switches 414 couple the switchable input nodes of the sampling capacitances C_{S} to the positive and negative input voltages V_{IP}, V_{IN}, respectively. A shorting switch opens a connection between the switchable input nodes of the sampling capacitances C_{S} during the sampling phase. When the sampling phase concludes, reset switches 709 open, sampling switches 714 open, and the shorting switch 716 closes. In this fashion, the sampling capacitances and associated switches operate as a sample and hold element.

With the sampling phase concluded, the control logic 702 iterates through the remaining phases of the digitization cycle, during which the comparator 104 produces a bit decision signal indicating whether the first sensing node V+ has a higher voltage than the second sensing node V−. If the phases are associated with an index i that progresses from n−1 to 0 (n being the number of bits desired in the digital representation of the input voltage) the bit decision signal Bᵢ takes on the value of the ith bit in the digital representation in the ith phase of the digitization cycle. A register 120 may capture these bit values to export the digital representation in a parallel or serial fashion. In at least some contemplated implementations, register 120 is a shift register.

The operation of the ADC is now described in connection with the flow diagram of FIG. 8. The digitization cycle begins in block 802 with an initial sampling phase, during which the control logic connects the first and second sensing nodes V+, V− to the common mode voltage V_{CM} while connecting the switchable nodes of the upper capacitances C_{i,P} in both banks to the upper reference voltage V_{ref} and the switchable nodes of the lower capacitances C_{i,N} in both banks to the lower reference voltage GND. At the same time, the control logic opens the shorting switch 716 and closes the sampling switches 714 to capture the positive and negative input voltages V_{IP}, V_{IN}. The sampling phase concludes in block 804 with the control logic opening the sampling switches 714, closing the shorting switch 716, and setting the phase index i to n−1.

In block 806, the comparator evaluates whether the first sensing node has a higher voltage than the second sensing node, and if so, asserts the bit decision signal Bᵢ in block 810. In block 812, the control logic determines whether the final phase (in which index i=0) has been reached. If so, the logic returns to block 802 to commence digitization of a new sample. If the final phase has not been reached, the control logic decrements the index i and connects the switchable node of the ith upper capacitance C_{i,P} in the first bank 710 to the lower reference voltage and the switchable node of the ith lower capacitance C_{i,N} in the second bank 712 to the upper reference voltage V_{ref}, thereby altering the voltage of the first and second sensing nodes as provided by the equations in block 830.

Otherwise, if the first sensing node has a lower voltage than the second sensing node, the comparator de-asserts the bit decision signal Bᵢ in block 820. In block 822, the control logic determines whether the final phase (in which index i=0) has been reached. If so, the logic returns to block 802 to commence digitization of a new sample. If the final phase has not been reached, the control logic decrements the index i in block 824 and connects the switchable node of the ith lower capacitance C_{i,N} to the upper reference voltage V_{ref} and the switchable node of the ith upper capacitance in the second bank to the lower reference voltage GND, thereby altering the voltage of the first and second sensing nodes as provided by the equations in block 830. Blocks 806-830 are repeated until index i reaches zero.

FIG. 9 shows the voltages of sensing nodes V+, V− for the sampling phase and first five digitization phases of an illustrative input voltage. During the sampling phase, the sensing nodes are connected to the common mode voltage V_{CM}. The switching array configuration created in block 804 causes the first sensing node to converge to the positive input voltage V_{IP} and the second sensing node to converge to the negative input voltage V_{IN}. When the phase index i=n−2, sensing node voltages are each shifted by V_{ref}/4. When the phase index i=n−3, the sensing node voltages are each shifted by V_{ref}/8. The direction of these shifts is determined by the bit decision signal Bᵢ.

As with the monotonic configuration of FIG. 4, the total capacitance requirements are halved and the voltage shifts are not reversed during the digitization process, enabling a substantial reduction in power consumption. As with the voltage waveforms of the non-monotonic configuration, however, each comparison by the comparator has the sensing node voltages spaced symmetrically about the common mode voltage, thereby maximizing accuracy.

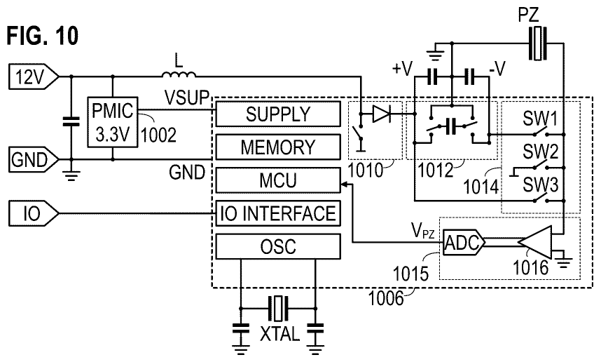

FIG. 10 shows a block diagram of an illustrative ultrasonic sensor. The illustrative sensor includes a power management IC (PMIC) 1002 that receives a 12V input and provides regulated 3.3V supply voltage to the remaining components, which include a sensor controller 1006, a piezoelectric element (PZ), a minimal number of discrete components such as inductors and capacitors, and an optional quartz crystal (XTAL) for timing control.

The illustrated transducer controller 1006 combines various integrated circuit modules including: a supply module for power distribution to the other controller components; a memory module (including, e.g., RAM, ROM, EEPROM, OTP) for storing configuration parameter values, operational data, and firmware; a microcontroller unit (MCU) for implementing sensor control logic; an input-output (IO) interface module for receiving and providing digital signals via an IO bus; an oscillator (OSC) module for clock generation with or without an external crystal; a DC-DC boost converter module 1010 for generating a programmable drive voltage; a voltage inverter 1012; a four-state transducer driver 1014; a programmable gain amplifier/attenuator (PGA) buffer 1016; and a balanced monotonic successive approximation ADC.

Boost module 1010 closes and opens a switch to alternately boost current flow in an inductor L and direct that current flow through a diode or transistor to raise a drive voltage +V on a first external capacitor. The ratio between the drive voltage +V and the 12V input voltage is determined by the duty cycle of the switch, enabling the boost module 1010 to control the drive voltage by varying the setpoint of the duty cycle.

The multi-state transducer driver 1014 has a first switch SW1 that selectively couples a drive terminal of the piezoelectric element PZ to the negative drive voltage-V; a second switch SW2 that selectively couples the drive terminal to ground, and a third switch SW3 that selectively couples the drive terminal to the positive supply voltage +V. If all three switches are open, the drive terminal is held in a high-impedance state. The driver can thus provide four states: a high-impedance state, a positive voltage state, a negative voltage state, and a ground state. Loosely speaking, the positive and negative voltage states may be used for driving the piezoelectric element to generate bursts of ultrasonic energy. The ground state may be used to suppress residual ringing of the piezoelectric element, and the high impedance state may be used to detect reflections (“echoes”) of the ultrasonic bursts.

A receiver 1015 includes a buffer amplifier 1016 to buffer the transducer's terminal voltage. The ADC digitizes the buffered transducer voltage, which corresponds to the voltage V_{PZ} across the piezoelectric transducer. The microcontroller operates on the digitized signal to derive the desired sensor measurements, e.g., distance, velocity, in accordance with established methods. The use of a balanced monotonic successive approximation ADC enables the sensor controller 1006 to operate with reduced power consumption and lower heat dissipation requirements.

It is contemplated that the control logic will be implemented as an application specific integrated circuit state machine, but understood that alternative implementations are possible and may be desirable, including firmware implemented by a programmable microcontroller. The capacitances are implementable as dielectric-separated metal layers formed in an integrated circuit manufacturing process or as reverse-biased P—N semiconductor junctions. The switches are contemplated to be p-channel or n-channel mosfets, but those of ordinary skill in the art will recognize that the disclosed designs are implementable using other forms of transistors and indeed other forms of switches. The disclosed designs are for differential input signals, but are readily adapted for use with single-ended input signals. And as previously mentioned, the illustrated capacitance banks employ binary-weighted capacitances, but other bank configurations that provide binary-weighted voltage shifts can be found in the literature and are suitable for modification in accordance with the disclosed principles.

While the dependent claims below are written to refer back to a single claim as a matter of claim drafting prescriptions in certain countries, it is observed that any combination of a dependent claim with any of its preceding claims is foreseen by the present inventors and is deemed included in the full disclosure of the present application. Furthermore, it is to be understood that the dependent claims depending from a given base claim will also be applicable to the other independent claims but have merely been omitted for the sake of limiting the overall number of claims and any claim fees that may be due as a result thereof.

What is claimed is:

1. An n-bit analog to digital converter that comprises:
a sample and hold element coupled to a first sensing node to provide an input voltage;
a first bank of capacitances configured to alter a voltage of the first sensing node in binary-weighted steps, the first bank including:
n−1 upper capacitances each having a switchable input node initially coupled to an upper reference voltage and switchable to a lower reference voltage; and
n−1 lower capacitances each having a switchable input node initially coupled to the lower reference voltage and switchable to the upper reference voltage, and a comparator configured to provide a bit decision signal based at least in part on a voltage of a first sensing node;
logic configured to control switches for the first bank of capacitances based on the bit decision signal, the bit decision signal providing a sequential binary representation of the input voltage.

2. The n-bit analog to digital converter of claim 1, wherein the sample and hold element provides the input voltage as a differential voltage provided between the first sensing node and a second sensing node, wherein the comparator provides the bit decision signal based on a voltage between the first sensing node and the second sensing node, and wherein the n-bit analog to digital converter further comprises:
a second bank of capacitances configured to alter the voltage of the second sensing node in binary-weighted steps, the second bank including:
n−1 upper capacitances each having a switchable input node initially coupled to an upper reference voltage and switchable to a lower reference voltage; and
n−1 lower capacitances each having a switchable input node initially coupled to the lower reference voltage and switchable to the upper reference voltage.

3. The n-bit analog to digital converter of claim 2,
wherein the logic operates in a sequence of phases including a sampling phase followed by n phases representable by an index i taking values from n−1 to 0,
wherein when the bit decision signal for phase i is zero, with i>0, the logic is configured to switch a corresponding lower capacitance in the first bank from the lower reference voltage to the upper reference voltage and a corresponding upper capacitance in the second bank from the upper reference voltage to the lower reference voltage, and
wherein when the bit decision signal for phase i is one, with i>0, the logic is configured to switch a corresponding upper capacitance in the first bank from the upper reference voltage to the lower reference voltage and a corresponding lower capacitance in the second bank from the lower reference voltage to the upper reference voltage.

4. The n-bit analog to digital converter of claim 3, wherein the sample and hold element includes:
a shorting switch configured to open or close a connection between a first sample node and a second sample node;
a first sample capacitance coupled between the first sample node and the first sensing node;
a second sample capacitance coupled between the second sample node and the second sensing node;
a first sample switch configured to couple the first sample node to a first voltage input while the shorting switch is open; and
a second sample switch configured to couple the second sample node to a second voltage input while the shorting switch is open.

5. The n-bit analog to digital converter of claim 4, wherein the sample and hold element further includes:
a first reset switch that couples the first sensing node to a mean voltage between the upper reference voltage and the lower reference voltage while the shorting switch is open; and
a second reset switch that couples the second sensing node to the mean voltage while the shorting switch is open.

6. The n-bit analog to digital converter of claim 1, wherein the first bank of capacitances includes a C₀ capacitance coupled between the lower reference voltage and the first sensing node, wherein the n−1 upper capacitances are given by Cᵢ=2ⁱ(C₀/2), i=0 to n−2, and wherein the n−1 lower capacitances are given by Cᵢ=2ⁱ(C₀/2), i=0 to n−2.

7. The n-bit analog to digital converter of claim 1, wherein the lower reference voltage is ground voltage.

8. A digitization method comprising:
coupling an input voltage to a first sensing node;
using a comparator to produce a bit decision signal based at least in part on a voltage of the first sensing node; and
altering the voltage of the first sensing node in binary-weighted steps by controlling switches for a first bank of capacitances based on the bit decision signal, thereby causing the bit decision signal to provide a sequential n-bit binary representation of the input voltage, the first bank of capacitances including:
n−1 upper capacitances each having a switchable input node initially coupled to an upper reference voltage and switchable to a lower reference voltage; and
n−1 lower capacitances each having a switchable input node initially coupled to the lower reference voltage and switchable to the upper reference voltage.

9. The digitization method of claim 8, wherein the input voltage is a differential voltage provided between the first sensing node and a second sensing node, wherein the comparator produces the bit decision signal based on a voltage between the first sensing node and the second sensing node, and wherein the altering further includes adjusting a voltage of the second sensing node in binary-weighted steps by controlling switches for a second bank of capacitances based on the bit decision signal, the second bank of capacitances including:
n−1 upper capacitances each having a switchable input node initially coupled to an upper reference voltage and switchable to a lower reference voltage; and
n−1 lower capacitances each having a switchable input node initially coupled to the lower reference voltage and switchable to the upper reference voltage.

10. The digitization method of claim 9,
wherein the altering is performed in a sequence of phases including a sampling phase followed by n phases representable by an index i taking values from n−1 to 0,
wherein when the bit decision signal for phase i is zero, with i>0, the altering includes switching a corresponding lower capacitance in the first bank from the lower reference voltage to the upper reference voltage and a corresponding upper capacitance in the second bank from the upper reference voltage to the lower reference voltage, and
wherein when the bit decision signal for phase i is one, with i>0, the altering includes switching a corresponding upper capacitance in the first bank from the upper reference voltage to the lower reference voltage and a corresponding lower capacitance in the second bank from the lower reference voltage to the upper reference voltage.

11. The digitization method of claim 10, wherein coupling the input voltage to the first sensing node is performed by a sample and hold element that includes:
a shorting switch configured to open or close a connection between a first sample node and a second sample node;
a first sample capacitance coupled between the first sample node and the first sensing node;
a second sample capacitance coupled between the second sample node and the second sensing node;
a first sample switch configured to couple the first sample node to a first voltage input while the shorting switch is open; and
a second sample switch configured to couple the second sample node to a second voltage input while the shorting switch is open.

12. The digitization of claim 11, wherein the sample and hold element further includes:
a first reset switch that couples the first sensing node to a mean voltage between the upper reference voltage and the lower reference voltage while the shorting switch is open; and
a second reset switch that couples the second sensing node to the mean voltage while the shorting switch is open.

13. The digitization method of claim 8, wherein the first bank of capacitances includes a C₀ capacitance coupled between the lower reference voltage and the first sensing node, wherein the n−1 upper capacitances are given by Cᵢ=2ⁱ(C₀/2), i=0 to n−2, and wherein the n−1 lower capacitances are given by Cᵢ=2ⁱ(C₀/2), i=0 to n−2.

14. The digitization method of claim 8, wherein the lower reference voltage is ground voltage.

15. A sensor controller that comprises:
one or more input pins configured to accept an analog signal from a transducer; and
a balanced monotonic successive approximation analog to digital converter configured to produce a digital signal representation of the analog signal.

16. The sensor controller of claim 15, wherein the balanced monotonic successive approximation analog to digital converter comprises:
a sample and hold element coupled to a first sensing node to provide an input voltage corresponding to the analog signal;
a first bank of capacitances configured to alter the voltage of the first sensing node in binary-weighted steps, the first bank including:
n−1 upper capacitances each having a switchable input node initially coupled to an upper reference voltage and switchable to a lower reference voltage; and
n−1 lower capacitances each having a switchable input node initially coupled to the lower reference voltage and switchable to the upper reference voltage, and
a comparator configured to provide a bit decision signal based at least in part on a voltage of a first sensing node;
logic configured to control switches for the first bank of capacitances based on the bit decision signal, the bit decision signal providing a sequential binary representation of the input voltage.

17. The sensor controller of claim 16, wherein the analog signal is a single-ended signal, the sensor controller further comprising an operational amplifier that amplifies the analog signal to produce a differential analog signal for the balanced monotonic successive approximation analog to digital converter.

18. The sensor controller of claim 17, wherein the sample and hold element provides the input voltage as a differential voltage provided between the first sensing node and a second sensing node, wherein the comparator provides the bit decision signal based on a voltage between the first sensing node and the second sensing node, and wherein the balanced monotonic successive approximation analog to digital converter further comprises:
a second bank of capacitances configured to alter the voltage of the second sensing node in binary-weighted steps, the second bank including:
n−1 upper capacitances each having a switchable input node initially coupled to an upper reference voltage and switchable to a lower reference voltage; and
n−1 lower capacitances each having a switchable input node initially coupled to the lower reference voltage and switchable to the upper reference voltage.

19. The sensor controller of claim 18, wherein the logic operates in a sequence of phases including a sampling phase followed by n phases representable by an index i taking values from n−1 to 0,
wherein when the bit decision signal for phase i is zero, with i>0, the logic is configured to switch a corresponding lower capacitance in the first bank from the lower reference voltage to the upper reference voltage and a corresponding upper capacitance in the second bank from the upper reference voltage to the lower reference voltage, and
wherein when the bit decision signal for phase i is one, with i>0, the logic is configured to switch a corresponding upper capacitance in the first bank from the upper reference voltage to the lower reference voltage and a corresponding lower capacitance in the second bank from the lower reference voltage to the upper reference voltage.

20. The sensor controller of claim 19, wherein the sample and hold element includes:
a shorting switch configured to open or close a connection between a first sample node and a second sample node;
a first sample capacitance coupled between the first sample node and the first sensing node;
a second sample capacitance coupled between the second sample node and the second sensing node;
a first sample switch configured to couple the first sample node to a first voltage input while the shorting switch is open;
a second sample switch configured to couple the second sample node to a second voltage input while the shorting switch is open;
a first reset switch that couples the first sensing node to a mean voltage between the upper reference voltage and the lower reference voltage while the shorting switch is open; and
a second reset switch that couples the second sensing node to the mean voltage while the shorting switch is open.
